(19) United States
(12) Patent Application Publication
(10) Pub. No.: US 2024/0117521 A1
(43) Pub. Date: Apr. 11, 2024

(54) METHOD AND SYSTEM FOR GROWING A LATTICE MATCHED, MULTILAYER, ORGANIC CRYSTAL HETEROSTRUCTURE

(71) Applicant: The Trustees of Princeton University, Princeton, NJ (US)

(72) Inventors: Barry Rand, Princeton, NJ (US); Jordan Dull, Saint Anthony, MN (US)

(73) Assignee: The Trustees of Princeton University, Princeton, NJ (US)

(21) Appl. No.: 18/374,765

(22) Filed: Sep. 29, 2023

Related U.S. Application Data
(60) Provisional application No. 63/412,713, filed on Oct. 3, 2022.

(51) Int. Cl. C30B 23/02; C30B 23/00; C30B 29/54

(52) U.S. Cl. CPC C30B 23/025; C30B 23/002; C30B 29/54

(57) ABSTRACT

Disclosed are criteria for a lattice matched, multilayer, organic crystal heterostructure. Current organic devices (e.g., photovoltaics, light emitting diodes, or transistors) rely on amorphous material despite superior charge transport properties of crystalline organic semiconductors. Achieving a fully crystalline device architecture requires growth of a molecular crystal atop a different one, or heteroepitaxy, and is particularly relevant in organic semiconductor devices that demand multiple layers of different molecules. This challenge is complicated when attempting to stack highly ordered layers needed for crystalline devices because strategies are needed to ensure that each layer grows crystalline. It is shown herein that lattice matching alone is not sufficient for successful organic heteroepitaxy deposited via physical vapor deposition. The process disclosed herein includes an additional criterion in which the lattice matched plane of the adlayer must also be the crystal face with the lowest surface energy. Application of this process leads to a full crystalline multilayer system in which there is perfect registry between the template layer and adlayer. Not only does this allow for the study of highly ordered interfaces, but it also opens the door to entirely crystalline device architectures, likely improving the efficiency over their amorphous counterparts.

### CROSS-REFERENCE TO RELATED APPLICATIONS

The present application claims priority to U.S. Provisional Patent Application No. 63/412,713, filed Oct. 3, 2022, the contents of which are incorporated by reference herein in its entirety.

### STATEMENT REGARDING FEDERALLY SPONSORED RESEARCH OR DEVELOPMENT

This invention was made with government support under Grant No. DE-SC0012458 awarded by the Department of Energy (DOE). The government has certain rights in the invention.

### TECHNICAL FIELD

The present disclosure relates to techniques for growing crystals, and specifically to methods and systems for growing a lattice matched, multilayer, organic crystal heterostructure.

### BACKGROUND

This section is intended to introduce the reader to various aspects of art, which may be related to various aspects of the present invention that are described and/or claimed below. This discussion is believed to be helpful in providing the reader with background information to facilitate a better understanding of the various aspects of the present invention. Accordingly, it should be understood that these statements are to be read in this light, and not as admissions of prior art.

Current organic devices (e.g., photovoltaics, light emitting diodes, or transistors) rely on amorphous material despite superior charge transport properties of crystalline organic semiconductors. Achieving a fully crystalline device architecture requires growth of a molecular crystal atop a different one, or heteroepitaxy, and is particularity relevant in organic semiconductor devices that demand multiple layers of different molecules.

Advancements in controlling and understanding thin film crystallization of organic semiconductors provide a foundation to integrate such films into fully crystalline device architectures. Achieving this goal requires growth of a molecular crystal atop a different one, or heteroepitaxy, and is relevant in organic semiconductor devices (e.g., photovoltaics, light emitting diodes, or transistors) that demand multiple layers of different molecules. This challenge is met with relative ease in disordered devices where the stacking or intermixing of different organic molecules can be realized without introducing dangling bonds. However, the task is more complicated when attempting to stack crystalline layers because strategies are needed to ensure that each layer grows crystalline.

For inorganic solids, heteroepitaxy succeeds on the basis of lattice matching due to the dominance of strong covalent and/or ionic bonds during the growth process. Inorganic materials can only withstand approximately 1% lattice mismatch before either dislocations form to relieve the strain or disordered growth occurs, impacting both optical and electronic properties.

In contrast, organic semiconductors are characterized by weak noncovalent interactions which result in a relaxation of the lattice matching requirement. In fact, this materials class can accommodate considerable lattice mismatch and still maintain crystalline heteroepitaxy—termed van der Waals epitaxy—a growth mechanism relevant to molecular or layered media. This has given rise to new classifications systems and growth modes ranging from weak epitaxial growth, quasiepitaxy, and molecular epitaxy. The latter argues that one of the driving forces in determining the orientational relationship between two crystals are corrugations arising from protrusions of atoms or chemical groups above the ideal surface. However, there is a paucity of evidence that this “corrugational force” will outcompete a commensurate system in which the two lattices are identical. This condition, sometimes called “one-to-one commensurism”, is akin to the lattice match requirement in inorganic heteroepitaxy and does not appear to be demonstrated in molecular systems.

### BRIEF SUMMARY

Various deficiencies in the prior art are improved upon by the disclosed systems and techniques.

In various aspects, a method for heteroepitaxially growing organic crystals may be provided. The method may include providing a template crystal. The method may include growing (e.g., via a technique such as physical vapor deposition) a first material having a crystal structure on top of the template crystal. The first material may be lattice matched to the template crystal and may have a matching plane that is the lowest energy of all planes of the crystal structure of the first material.

In various aspects, a method for selecting materials for heteroepitaxially growing organic crystals may be provided. The method may include identifying a template crystal structure and the in-plane lattice parameters of the template crystal structure. The method may include determining a lattice matched material (e.g., as one material from a plurality of known materials). The determination may include comparing lattice parameters of each crystal plane of the lattice matched material to the in-plane (i.e., parallel to the substrate) lattice parameters of the template crystal structure. The lattice matched material may have a matched plane. The matched plane may have the lowest surface energy of all crystal planes of the lattice matched material. In some embodiments, the method may include calculating relative surface energies of the lattice matched material via first principles methods or estimated by applying Bravais-Friedel-Donnay-Harker law to determine a largest area of a crystal morphology, the largest area having the lowest energy surface.

In some embodiments, the lattice matched material may be free of polymorphs. In some embodiments, the lattice matched material may be the most stable polymorph of a plurality of polymorphs.

In some embodiments, the method may include growing the lattice matched material with the lowest surface energy on top of the template crystal (e.g., via physical vapor deposition).

In various aspects, a system for selecting materials for heteroepitaxially growing organic crystals may be provided. The system may include at least one processor and a non-transitory computer readable storage medium. The storage medium may contain instructions that, when executed, configures the at least one processor to, collectively, perform various steps. The steps may include receiving information about a template crystal structure. The steps may include identifying a first material that is lattice matched to a template crystal structure by comparing lattice parameters of each crystal plane of the first material to the in-plane lattice parameters of the template crystal structure, and identifying a matched plane to the in-plane lattice of the template crystal structure. The matched plane may have the lowest surface energy of all crystal planes of the first material.

In some embodiments, identifying the first material may include estimating relative surface energies of the first material by applying first principles methods or Bravais-Friedel-Donnay-Harker law to determine a largest area of a crystal morphology, the largest area having the lowest energy surface.

In some embodiments, the information about the template crystal structure may include a material of the template crystal structure or a code representative of the material. In some embodiments, the information about the template crystal structure may include in-plane lattice parameters of the template crystal structure. In some embodiments, the at least one processor is further configured to identify a template crystal structure and the in-plane lattice parameters of the template crystal structure.

The at least one processor may be further configured to grow the first material. This may include being configured to control a physical vapor deposition process to grow the first material on top of the template crystal structure.

The at least one processor may be further configured to determine growth conditions for growing the first material on top of the template crystal structure. The at least one processor may be further configured to then store and/or transmit the growth conditions. This may be done by, e.g., storing the growth conditions on the non-transitory computer readable storage medium, storing the growth conditions on a second, removable non-transitory computer readable storage medium, sending the growth conditions to a remote device, or a combination thereof.

### BRIEF DESCRIPTION OF FIGURES

The accompanying drawings, which are incorporated in and constitute a part of this specification, illustrate embodiments of the present invention and, together with a general description of the invention given above, and the detailed description of the embodiments given below, serve to explain the principles of the present invention.

FIGS. 1A-1H are the molecular structures of rubrene (1A), diindenylphenylphosphine selenide (DIPPSe) (1B), 1,3,5-tris(1-phenyl-1H-benzimidazol-2-yl)benzene (TPBi) (1C), N2,N2,N4,N4,N6,N6-hexa(pyridin-2-yl)-1,3,5-triazine-2,4,6-triamine (HPTT) (1D), 1,2,3,5-tetrakis(carbazol-9-yl)-4,6-dicyanobenzene (4CzIPN) (1E), bis[2,2′-(1H-1,2,4-triazole-3,5-diyl) bis(phenolato)]-titanium(iv) (Ti(BHPT)₂) (1F), 2,2′-bis(diphenylphosphino)-1,1′-binaphthalene (rac-BINAP) (1G), and methyl (triphenylphosphoranylidene)acetate (MTPPA) (1H)

FIG. 2 is a schematic of the overlap between a template and an overlayed crystal.

FIG. 3 is an ultraviolet photoelectron spectroscopy (UPS) valence spectra of crystalline and amorphous 4CzIPN and Ti(BHPT)₂, with shifted valence states in linear scale with energy-matched peaks: A, B, C, and D.

It should be understood that the appended drawings are not necessarily to scale, presenting a somewhat simplified representation of various features illustrative of the basic principles of the invention. The specific design features of the sequence of operations as disclosed herein, including, for example, specific dimensions, orientations, locations, and shapes of various illustrated components, will be determined in part by the particular intended application and use environment. Certain features of the illustrated embodiments have been enlarged or distorted relative to others to facilitate visualization and clear understanding. In particular, thin features may be thickened, for example, for clarity or illustration.

### DETAILED DESCRIPTION

The following description and drawings merely illustrate the principles of the invention. It will thus be appreciated that those skilled in the art will be able to devise various arrangements that, although not explicitly described or shown herein, embody the principles of the invention and are included within its scope. Furthermore, all examples recited herein are principally intended expressly to be only for illustrative purposes to aid the reader in understanding the principles of the invention and the concepts contributed by the inventor(s) to furthering the art and are to be construed as being without limitation to such specifically recited examples and conditions. Additionally, the term, “or,” as used herein, refers to a non-exclusive or, unless otherwise indicated (e.g., “or else” or “or in the alternative”). Also, the various embodiments described herein are not necessarily mutually exclusive, as some embodiments can be combined with one or more other embodiments to form new embodiments.

The numerous innovative teachings of the present application will be described with particular reference to the presently preferred exemplary embodiments. However, it should be understood that this class of embodiments provides only a few examples of the many advantageous uses of the innovative teachings herein. In general, statements made in the specification of the present application do not necessarily limit any of the various claimed inventions. Moreover, some statements may apply to some inventive features but not to others. Those skilled in the art and informed by the teachings herein will realize that the invention is also applicable to various other technical areas or embodiments.

It is shown herein that the lattice matching requirement alone is not sufficient for successful organic heteroepitaxy. As disclosed herein, heteroepitaxy can be improved upon by requiring—in addition to the lattice matching requirement—an additional criterion in which the lattice matched plane of the adlayer must also be the crystal face with the lowest surface energy.

Application of this process leads to a full crystalline multilayer system in which there is perfect registry between the template layer and adlayer. Not only does this allow for the study of highly ordered interfaces, but it also opens the door to entirely crystalline device architectures, likely improving the efficiency over their amorphous counterparts.

More particularly, disclosed are a method for heteroepitaxially growing organic crystals and a system for selecting materials for heteroepitaxially growing organic crystals, premised upon the material selection criteria disclosed herein that allows one to grow organic crystals on top of each other.

Initially, the disclosed process can be used, inter alfa, to study the impact highly ordered interfaces have on optical and electrical properties of organic semiconductors. The disclosed approach can also be used to, for example, incorporate organic crystalline multilayers into electronic devices like solar cells, light emitting diodes (LED), and transistors, and may apply to pharmaceutical industry entities that deal with co-crystals and multiple molecules.

The material selection criteria needed to achieve heteroepitaxial growth disclosed herein include 1) lattice matching and 2) having the lattice matched plane be the lowest energy surface.
1) The lattice matching requirement (lattice parameters of the two different materials are nearly identical) is well documented in inorganic heteroepitaxy. Prior hereto, it was unknown whether this is also the case for organic materials.
2) The lattice matched plane must also be the lowest energy surface. Due to the prominence of relatively weak van der Waals forces in organic semiconductors, bonding between different materials is not as strong as inorganic materials (which feature interatomic covalent and/or ionic bonding). Therefore, perfect lattice matching is not a strong enough driving force to grow an organic crystal in a certain orientation. If, however, the lowest energy surface is also the lattice matched one, the system is energetically inclined to grow with the lattice matched planes adjacent in a multilayered crystalline fashion.

The disclosed process shows it is possible to grow organic crystals commensurately, a first for organics.

In various aspects, a method for selecting materials for heteroepitaxially growing organic crystals may be provided. The method may include identifying a template crystal structure and some or all of the in-plane lattice parameters of the template crystal structure.

Any appropriate crystalline material may be used. In some embodiments, the material may be a material commonly used in photon conversion processes, such as an acceptor molecule (e.g., rubrene or TPBi), or a donor-acceptor molecule (e.g., 1,2,3,5-tetrakis(carbazol-9-yl)-4,6-dicyanobenzene (4CzIPN)).

Once the template crystal structure has been identified, the method may include determining a lattice matched material. In some embodiments, this may be, e.g., one material from a plurality of known materials. In some cases, a library of known materials may exist, that may include crystalline material names and lattice parameters for different planes of the known material. In some cases, one or more options for a material to be grown on the template crystal structure may be known or provided.

The determination may include comparing at least one lattice parameter of each crystal plane of the lattice matched material to the in-plane lattice parameters of the template crystal structure. As used herein, the term “lattice matched” indicates that the two referenced materials have the same or lattice constants differing by up to ±3%, preferably up to ±1%, more preferably up to ±0.5%, and still more preferably up to ±0.2%. For example, the (100) plane of rubrene and the (001) plane of DIPPSe are lattice matched, having lattice constants differing by less than 0.2%.

The lattice matched material may have a matched plane. The matched plane may have the lowest surface energy of all crystal planes of the lattice matched material. Any appropriate technique for determining surface energies may be used. For example, to determine whether the surface energy criteria is met, the method may include, e.g., calculating relative surface energies of the lattice matched material via first principles methods or estimating by applying Bravais-Friedel-Donnay-Harker law to determine the largest area of a crystal morphology, where the largest area has the lowest energy surface.

The method may include filtering a database of potential lattice matched materials based on desired parameters. For example, the database of materials could be filtered based on molecular weight (e.g., having a molecular weight that is at or above a lower threshold, and/or at or below an upper threshold). The database could be filtered based on whether the material is a solvated crystal. The database could be filtered based on the existence or lack of a particular structural feature (such as a conjugated ring, the presence of a particular functional group, etc.), and/or a class of material (such as, e.g., whether the material is a conductor/semiconductor/insulator, an acceptor/donor, a fluorescent material, etc.)

The method may include determining if the material has polymorphs. In some embodiments, the lattice matched material may be free of polymorphs. With respect to whether a material has multiple polymorphs, some polymorphs may be more stable than the crystal structure identified as a match and therefore outcompete a preferred morphology. Therefore, in some embodiments, the lattice matched material may be the most stable polymorph of a plurality of polymorphs. In some embodiments, the method may include determining the number of single bonds in a potential lattice matched material. A molecule with a large number of single bonds (e.g., a number of single bonds above a predetermined threshold) may lead to more polymorphs, so in some embodiments, a selected lattice matched material may have a number of single bonds below a predetermined threshold.

The method may include comparing at least one thermal property of the lattice matched material to the same thermal properties of the template crystal structure. In particular, in some embodiments, if a glass transition temperature (T_{g}) of the lattice matched material is too low (e.g., below a first predetermined threshold), the film it forms may not be stable and change over time. Similarly, if the T_{g} of the lattice matched material is too high (e.g., above a second predetermined threshold), it may be challenging to achieve a substrate temperature hot enough to allow for crystal growth. To avoid these issues, the method may include checking whether a material's thermal properties are in an appropriate range before selecting the lattice matched material to work with.

To heteroepitaxially grow organic crystals, the method may include providing a template crystal. The method may include growing the lattice matched material (e.g., a first material) on top of the template crystal. The first material may be lattice matched to the template crystal and may have a matching plane that is the lowest energy of all planes of the crystal structure of the first material. Any appropriate technique for growing the crystal may be used. In some embodiments, the lattice matched material is grown via physical vapor deposition. As will be understood, growth conditions (e.g., deposition rate, substrate temperature, etc.) must be modified on a case-by-case basis.

In some embodiments, the method may include verifying one or more lattice parameters related to the structure of the grown lattice-matched material using any appropriate technique, such as x-ray diffraction or electron diffraction.

In various aspects, a system for selecting materials for heteroepitaxially growing organic crystals may be provided. The system may include at least one processor and a non-transitory computer readable storage medium. The storage medium may contain instructions that, when executed, configures the at least one processor to, collectively, perform various steps.

The steps may include receiving information about a template crystal. In some embodiments, the information about the template crystal may include a material of the template crystal or a code representative of the material. In some embodiments, the information about the template crystal may include the template crystal structure and the in-plane lattice parameters of the template crystal structure.

The steps may include identifying the in-plane lattice parameters of the template crystal structure. This may be part of the information received about the template crystal structure. In some embodiments, the at least one processor is further configured to identify the in-plane lattice parameters of the template crystal structure. In some embodiments, this may include, e.g., using x-ray diffraction to determine the parameters of the template crystal structure. In some embodiments, this may include, e.g., retrieving the parameter(s) from a database.

The steps may include identifying a first material that is lattice matched to the template crystal structure by comparing at least one lattice parameter of each crystal plane of the first material to the in-plane lattice parameters of the template crystal structure, and has a matched plane to a plane of the template crystal structure. The matched plane may have the lowest surface energy of all crystal planes of the first material.

In some embodiments, identifying the first material may include estimating relative surface energies of the first material by applying first principles methods or Bravais-Friedel-Donnay-Harker law to determine a largest area of a crystal morphology, the largest area having the lowest energy surface.

The at least one processor may be further configured to grow the first material. This may include being configured to control a physical vapor deposition process, such as controlling growth conditions, to grow the first material on top of the template crystal as disclosed herein.

The at least one processor may be further configured to determine growth conditions for growing the first material on top of the template crystal. As disclosed herein, this may include comparing one or more thermal parameters of the lattice matched material. This may include retrieving growth conditions from one or more databases. This may include retrieving previously used growth conditions and results of those growth conditions from one or more databases. This may include modifying previously used conditions, based on a change in one or more of the materials, and/or based on a past result of using those growth conditions (e.g., to optimize a previous set of conditions). This may include modifying a previously utilized deposition rate and/or substrate temperature.

The at least one processor may be further configured to then store and/or transmit the determined growth conditions. This may be done by, e.g., storing the growth conditions on the non-transitory computer readable storage medium, storing the growth conditions on a second, removable non-transitory computer readable storage medium, sending the growth conditions to a remote device, or a combination thereof.

### EXAMPLE

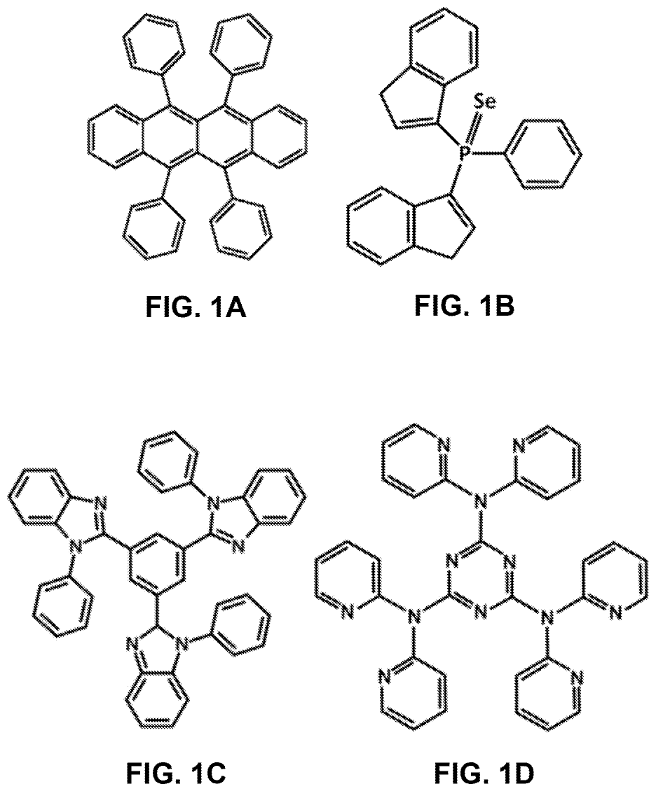

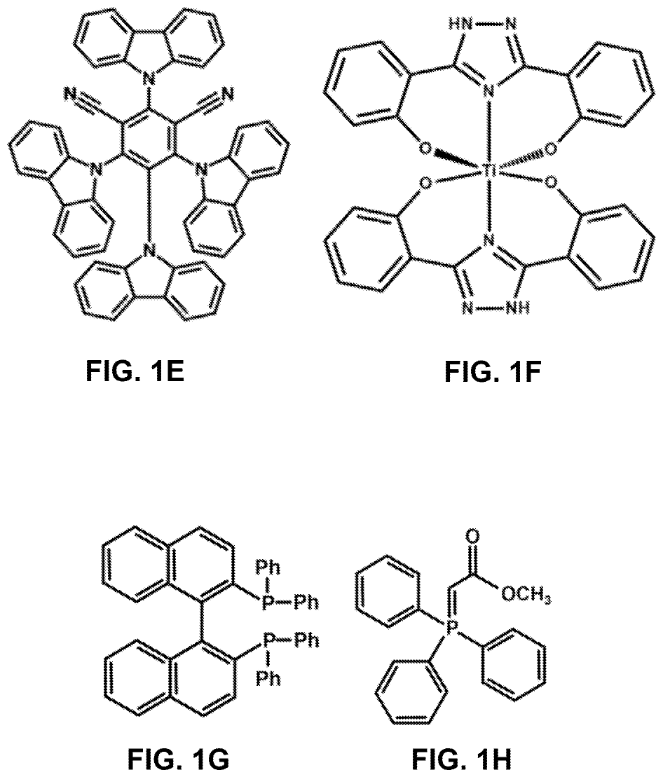

Thin film crystals of rubrene (see FIG. 1A), TPBi (see FIG. 1C), 4CzIPN (see FIG. 1E), and rac-BINAP (see FIG. 1G) were used as template crystal structures.

Template crystals were made on glass/indium tin oxide (ITO) substrates that were cleaned successively by sonication in deionized water with Extran soap in a 6:1 ratio, deionized water, acetone, and isopropanol followed by an oxygen plasma treatment. Silicon nitride (SiN) transmission electron microscope (TEM) grids were cleaned only by an oxygen plasma treatment before use. All material deposition steps were completed by thermal evaporation at a base pressure of ˜10⁻⁷ Torr. All annealing steps were done in a nitrogen filled glovebox on a preheated hotplate. Annealing conditions used to form the rubrene, TPBi, and 4CzIPN crystalline templates can be found in Dull, J. T., et al., “Thermal Properties, Molecular Structure, and Thin-Film Organic Semiconductor Crystallization”, J. Phys. Chem. C. 2020, 124, 27213-27221. For the rac-BINAP template, a 60 nm film was annealed at 140° C. for 5 min.

For each crystal template, the out-of-plane orientation, and therefore the lattice parameters of the plane parallel to the substrate, were determined by x-ray diffraction (XRD), with a Bruker D8 DISCOVER® X-Ray Diffractometer with a copper source and a wavelength of 1.54 Å. These data are listed in Table 1, below.

Then, molecular crystals with lattice planes matched to the template crystals were identified.

The Cambridge Structural Database (CSD) Python application programming interface (API) was used to access the crystal structures and molecular information contained in the Cambridge Crystallographic Data Centre (CCDC). The CCDC identification codes of the crystal structures used in this example are QQQCIG11 (rubrene), XAZGUC (rac-BINAP), YUGDOV (4CzIPN), INAMAL (DIPPSe) (see FIG. 1B), XIZFER03 (HPTT) (see FIG. 1D), PECBEH (Ti(BHPT)₂) (see FIG. 1F), and TPCMOM01 (MTPPA) (see FIG. 1H). The structure used for TPBi in this example was determined in-house, but a nearly identical structure was solved with the identification code JUXSUT01.

Prior to running the lattice match program on the template crystal lattices, non-relevant materials or crystals were filtered out of the CSD. The selection rules included: i) having a molecular weight greater than 300 g/mol to minimize vapor pressure under vacuum conditions, ii) having a molecular weight less than 1000 g/mol due to likely degradation when attempting to evaporate it, iii) entries containing only one type of molecule to eliminate solvated crystals, and iv) at least one fully conjugated ring in an attempt to study only semiconducting materials. At the time of this work, the application of these filters to the entirety of the CSD resulted in 280,480 crystal entries.

The resulting list of materials was then ranked based on their closeness of fit to a chosen template crystal lattice. The script in this example considered the (100), (010), (001), (110), (101), and (011) planes of each candidate material when searching for a match. Higher index planes were ignored as they tend to have smaller interplanar distances than primary planes, which according to Bravais-Friedel-Donnay-Harker (BFDH) law means they are not as morphologically important and less likely to be exposed during crystal growth. However, in various embodiments, such higher index planes may be included.

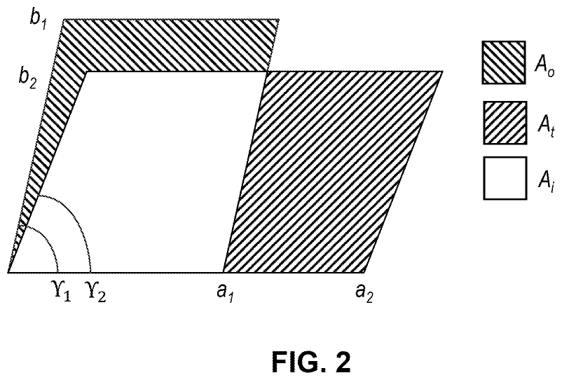

For each plane there exists a triplet consisting of two lengths and an angle. From this triplet, a parallelogram can be constructed representing a unit cell of that plane. Doing this for both the template and the overlayer we can calculate the area of each parallelogram, Aₜ and Aₒ, respectively. By aligning one corner and one edge of the template and the overlayer parallelograms, as shown in FIG. 2, one can also determine the area of intersection, Aᵢ.

In this example, the lattice parameters associated with the (001) plane of each material are used to create parallelograms with a shared origin. The area of the template parallelogram (Aₜ), overlayer parallelogram (Aₒ), and their intersection (Aᵢ) are indicated by the various hatched and unhatched areas.

Finally, the fit parameter, m, is defined as

$$m = \frac{{A}_{t} + {A}_{o} - 2 {A}_{i}}{{A}_{t}} \qquad ( 1 )$$

Therefore, if two materials are perfectly lattice matched (Aₜ=Aₒ=Aᵢ) then m will equal 0. This condition is defined as one-to-one commensurism. This would also be the case for homoepitaxy, where the overlayer is the same material as the template. In the limit where there is very little overlap (near perfect lattice mismatch) then the value m approaches

$$1 + \frac{{A}_{o}}{{A}_{t}} .$$

To find lattice matched pairs, the triplet of a template crystal (listed in Table 2, below) is input into the Python script. Each entry in the filtered CCDC database has six m values calculated (for the six planes checked in this example) and the lowest m was returned along with its associated plane.

This plane is then checked to see if it is the lowest energy crystal face. The relative surface energy of each crystal plane is estimated by employing the Wulff theorem which concludes that the largest face of a crystal also has the lowest surface energy. By implementing the BFDH morphology predicted for a crystal, the relative area each plane contributes to the crystal form, and therefore that plane's relative surface energy, can be estimated. The plane with the lowest surface energy for each material is listed in Table 2. Notably, of the overlayers, only DIPPSe has a mismatch between the lowest surface energy and the lattice matched plane. While this is a purely geometric argument to determine the lowest energy crystal plane and ignores the kinetic factors of crystal growth, the BFDH morphology is useful for two reasons. First, as disclosed herein, it is expected that the lowest energy plane of a thin film crystal to be the plane parallel to the substrate because that maximizes its area. In fact, good agreement was found between the basal planes of our template crystals and their BFDH predicted lowest energy surfaces, as listed in Table 2. Without being held to any particular theory, this was attributed to the fact that this example is only concerned with relative surface energies and not absolute values. Secondly, the BFDH morphology is quickly determined through the CSD Python API which makes it practical to use when calculating it for hundreds of thousands of materials.

TABLE 1
Lattice parameters of the crystal templates and their respective
lattice matched materials for the given plane. For each pair,
the top material is the template, and the bottom material is
the overlayer. Miller indices are provided for the experimentally
determined out-of-plane orientation of the template crystals
and lattice matched plane of overlayer materials.

| | Lattice | Lattice | | |
|---|---|---|---|---|
| Material | Parameter (Å) | Parameter (Å) | Angle (°) | Plane (hkl) |
| Rubrene | 7.19 | 14.43 | 90 | (100) |
| DIPPSe | 7.18 | 14.43 | 90 | (001) |
| TPBi | 19.31 | 12.69 | 90 | (001) |
| HPTT | 19.44 | 12.68 | 90 | (100) |
| rac-BINAP | 9.2 | 19.12 | 90 | (100) |
| MTPPA | 8.99 | 19.05 | 90 | (001) |
| 4CzIPN | 9.0 | 19.58 | 89.9 | (001) |
| Ti(BHPT)₂ | 9.0 | 19.61 | 90 | (001) |

TABLE 2
Lattice parameters of the crystal templates and their respective lattice
matched materials, including the strain along each axis (ε) and
lattice match parameter (m). Miller indices are provided for (exp)
the experimentally determined out-of-plane orientation of the template
crystals, (lm) lattice matched plane of overlayer material, and (lse)
the lowest surface energy plane as predicted by the BFDH method.

| Template | Triplet | Overlayer | Triplet | | |
|---|---|---|---|---|---|
| (hkl) | (Å, Å, °) | (hkl) | (Å, Å, °) | ϵ (%) | m |
| Rubrene | 7.19 | DIPPSe | 7.18 | 0.17 | 0.0010 |
| (100)ₑₓₚ | 14.43 | (001)ₗₘ | 14.43 | 0.05 | |
| (200)ₗₛₑ | 90 | (10-1)ₗₛₑ | 90 | — | |
| TPBi | 19.31 | HPTT | 19.44 | 0.66 | 0.0071 |
| (001)ₑₓₚ | 12.69 | (100)ₗₘ | 12.68 | 0.07 | |
| (002)ₗₛₑ | 90 | (100)ₗₛₑ | 90 | — | |
| rac-BINAP | 9.2 | MTPPA | 8.99 | 2.26 | 0.267 |
| (100)ₑₓₚ | 19.12 | (001)ₗₘ | 19.05 | 0.39 | |
| (002)ₗₛₑ | 90 | (001)ₗₛₑ | 90 | — | |
| 4CzIPN | 9.0 | Ti(BHPT)₂ | 9.0 | 0.03 | 0.0069 |
| (001)ₑₓₚ | 19.58 | (001)ₗₘ | 19.61 | 0.17 | |
| (001)ₗₛₑ | 89.9 | (001)ₗₛₑ | 90 | — | |

The growth conditions of the overlayers were as follows: DIPPSe was deposited on rubrene at a rate of 0.05 Å/s with the template held at room temperature, HPTT was deposited on TPBi at a rate of 0.1 Å/s with the template held at 100° C., and MTPPA was deposited on TPBi at a rate of 0.1 Å/s with the template held at 10° C. Deposition rates were determined by a quartz crystal microbalance. An HPTT-only crystalline film was prepared by depositing 80 nm of HPTT onto glass/ITO and annealing it at 180° C. for 5 min in a nitrogen filled glovebox.

Due to the high temperatures needed for growth of crystalline Ti(BHPT)₂, two strategies were implemented to grow this molecule on 4CzIPN templates.

The first strategy involved growing Ti(BHPT)₂ on a 4CzIPN template held at a temperature of approximately 160° C. using a deposition rate of 0.01 Å/s. These samples were used to measure the atomic force microscope (AFM) and x-ray diffraction (XRD) data. Note that the 4CzIPN template is formed by annealing at 200° C. and melts at 378° C., making it stable at 160° C. for the extended time required for adlayer deposition. The Ti(BHPT)₂ was deposited by sublimation from a Knudsen cell held around 325° C. that was thoroughly outgassed prior to deposition.

The second strategy employed a post-deposition annealing technique to grow this heterostructure on glass/ITO and SiN membranes, the latter of which is compatible with TEM. A thin layer of Ti(BHPT)₂ was deposited on a crystalline 4CzIPN template held at room temperature using a deposition rate of 0.1 Å/s. These conditions result in an amorphous Ti(BHPT)₂ film, but post-deposition annealing at 190-200° C. crystallizes the Ti(BHPT)₂ layer. This method is effective for Ti(BHPT)₂ thicknesses up to 5 nm, at which point the adlayer remains amorphous. The layer thicknesses used for UPS and IPES were 20 nm of 4CzIPN and 3 nm of Ti(BHPT)₂.

The matched plane and lattice constants for the selected materials are given in Table 1, above. Notably, the percent mismatch along each axis is less than 1% in nearly all cases, implying remarkably close fits between crystal structures composed of completely distinct molecules. Of the four overlayers, three were chosen such that the lattice matched plane is also the lowest surface energy plane. The remaining overlayer does not meet this condition for the purpose of testing the criterion that one-to-one commensurate epitaxy requires the lowest energy plane and lattice matched plane to be the same.

Beginning with this case, diindenylphenylphosphine selenide (DIPPSe) was chosen for growth atop rubrene (100) because its lattice matched (001) plane is not its lowest energy plane. The DIPPSe layer forms large spherical aggregates suggesting amorphous growth, which was confirmed by XRD. Other growth conditions were attempted (see Table 3, below), but all similarly failed to show crystalline growth of the adlayer. Thus, simply having two materials with crystal structures with near-perfect lattice matching is insufficient to guarantee crystalline adlayer growth, much less one-to-one commensurate epitaxy.

TABLE 3
Growth conditions for DIPPSe grown on rubrene template.

| Growth | Growth rate & | Post-deposition | | Thick- |
|---|---|---|---|---|
| Condi- | Substrate Temperature | annealing | Subsequent | ness |
| tion | (Å/s; ° C.) | (° C.; min) | growth | (nm) |
| 1 | 0.1; 80 | — | — | 40 |
| 2 | 0.05; 100 | — | — | 15 |
| 3 | 0.05; Room Temp | — | — | 25 |
| 4 | 1; −15 | 100; 5 | — | 20 |
| 5 | 1; −15 | 100; 5 | 0.1 Å/s; | 20; 20 |
| | | | Room Temp | |
| 6 | 1; −10 | 120; 30 | — | 20 |

In addition to surface energy constraints; two other factors may be capable of precluding commensurate epitaxy. Turning to the case of TPBi, HPTT was utilized, which has its (001) plane lattice matched to the (001) plane of TPBi and is the lowest energy crystal face. In this case, HPTT did show crystal formation on the TPBi template. However, characterizing these films with XRD, it was found that, along with the reflections from the TPBi template, there appear two reflections originating from the HPTT adlayer. We assign the peak at 18° to the (040) plane of the known crystal structure of HPTT, but the peak at 8° eludes indexing. When an HPTT film is crystallized without a template, we find the 8° reflection but the (040) peak is absent. This suggests the coexistence of the known crystal phase and a thin film phase, or polymorph, of HPTT when grown on a TPBi template. This was confirmed by grazing incident x-ray diffraction (GIXD) measurements on these heterostructures and single-layer films.

Therefore, in the context of identifying candidate materials that can grow commensurately on a template crystal, it may be beneficial to minimize the number of potential polymorphs.

Another lattice and energy matched material system, composed of rac-BINAP and MTPPA, illustrates how thermal stability of the adlayer crystal may also be considered.

The (100) plane of the rac-BINAP template was matched to the (001) plane of MTPPA, which is also the lowest energy plane of the MTPPA crystal (see molecular structures in FIGS. 1G and 1H. While initial heteroepitaxy growth and measurements of this system appear promising, we found subsequent AFM scans of the same area on the rac-BINAP/MTPPA heterostructure were not reproducible. In fact, scans taken immediately after one another show that the MTPPA surface evolves over time. Of the material systems studied in this example, this was the only one to behave in this way. Height distribution graphs for each AFM scan show a gradual increase in height of the MTPPA layer while increasing amounts of the rac-BINAP surface is exposed. This aggregation is attributed to the low glass transition temperature (T_{g}) of MTPPA of 20° C. measured by differential scanning calorimetry. As soon as the bilayer is removed from the cold substrate holder and warmed to room temperature (above its T_{g}), MTPPA has sufficient thermal energy to reorganize.

In order to capture the heterostructure before MTPPA significantly changes its morphology on the rac-BINAP surface, AFM and XRD measurements were taken immediately after MTPPA was deposited onto a template held at 10° C. The AFM scan shows rectangular-shaped terraces indicative of crystalline growth. The XRD pattern shows the diffraction peaks from MTPPA's (001) family of planes along with the reflections from the rac-BINAP template. This provides strong evidence that MTPPA grows in the expected out-of-plane orientation for one-to-one commensurate growth on MTPPA. However, to verify the in-plane orientation selected area electron diffraction (SAED) is required. Given the thermal instability of the MTPPA layer, SAED is impractical. Therefore, in some embodiments, it may be advantageous to require a lattice matched material's T_{g} be significantly higher than room temperature. In some embodiments, the lattice matched material's T_{g} may be at least 40° C. In some embodiments, the lattice matched material's T_{g} may be at least 50° C. In some embodiments, the lattice matched material's T_{g} may be at least 75° C. In some embodiments, the lattice matched material's T_{g} may be at least 100° C. In some embodiments, the lattice matched material's T_{g} may be at least 125° C. In some embodiments, the lattice matched material's T_{g} may be at least 150° C. In some embodiments, the lattice matched material's T_{g} may be at least 200° C.

For the 4CzIPN template, Ti(BHPT)₂ was identified for which the (001) plane is both the lowest energy surface and lattice matched to the (001) plane of 4CzIPN. Molecular structures of these molecules are shown in FIGS. 1E and 1F. Crystalline growth of Ti(BHPT)2 on 4CzIPN templates was achieved, as evidenced by AFM and XRD. Inspecting the AFM scan, the consistently shaped and faceted islands formed by Ti(BHPT)₂ were noted as one of the classic growth modes in crystalline epitaxy implying growth beyond several nm is crystalline. The XRD data revealed a strong reflection originating from Ti(BHPT)₂ (001) at approximately 8.5° and which is the crystal plane lattice matched to 4CzIPN.

To confirm one-to-one commensurate epitaxy, the azimuthal orientation was determined between the 4CzIPN template and Ti(BHPT)₂ using selected area electron diffraction (SAED) The post-deposition annealing technique disclosed herein was employed to grow the 4CzIPN/Ti(BHPT)₂ heterostructures on silicon nitride membranes compatible with a transmission electron microscope (TEM). Similar samples were prepared on glass/ITO substrates with the resulting AFM scans. Particularly in the 1 nm thick adlayer case, highly directional growth of the Ti(BHPT)₂ crystal was found. An AFM across a 4CzIPN grain boundary clearly shows that Ti(BHPT)₂ changes orientation with the template, implying registry between the layers.

Considering the SAED diffraction pattern of the 4CzIPN template, since the zone axis is parallel to the normal of 4CzIPN (001), the diffraction spots occur from the (0 kl) set of planes. Indeed, the interplanar spacing, d, of these reflections yield d(100)=8.94±0.04 Å and d₍₀₁₀₎=19.2±0.04 Å which are consistent with the spacing predicted from the crystal structure: 8.94 Å and 19.15 Å, respectively.

The diffraction pattern of a 4CzIPN/ Ti(BHPT)₂ (3 nm) heterostructure is a superposition of reflections from both 4CzIPN and Ti(BHPT)₂. While the majority of the reflections originate from 4CzIPN, diffraction spots from Ti(BHPT)₂ can be identified. If Ti(BHPT)₂ grows commensurately on 4CzIPN it should be expected each Ti(BHPT)2 reflection to occur exactly in-line with 4CzIPN's a*-axis, as both crystals have planes with d-spacings of approximately 9 Å along this direction and that are parallel to the electron beam. The * symbol denotes a reciprocal lattice vector. In fact, the reflections of Ti(BHPT)₂ do fall nicely in-line with the 4CzIPN reflections. Calculating the (010) spacing of Ti(BHPT)₂ results in d₍₀₁₀₎=8.98±0.05 Å, further supporting the fact that Ti(BHPT)₂ registers with 4CzIPN as predicted.

Taken together, the XRD data providing information on the out-of-plane Ti(BHPT)₂ orientation, combined with SAED showing the correct in-plane alignment along 4CzIPN's a*-axis proves that the Ti(BHPT)₂ crystalline adlayer must be registering with 4CzIPN one-to-one commensurately. Considering two SAED patterns on neighboring 4CzIPN grains, the Ti(BHPT)₂ reflections remain aligned with the underlying lattice. Similar to the AFM scan, this shows that the 4CzIPN underlayer is the driving force that orients the Ti(BHPT)₂ crystals in the manner of one-to-one commensurate heteroepitaxy. The two primary factors that appear to drive this relationship (out-competing surface corrugations) are that both material's (001) planes are well lattice matched and that the (001) plane of Ti(BHPT)₂ is the lowest surface energy facet.

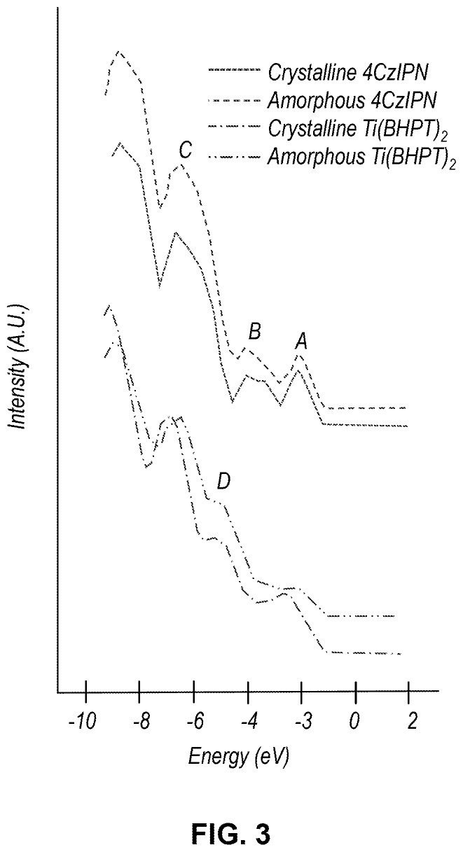

To demonstrate differences between the electronic states of amorphous (a-) and crystalline (c-) 4CzIPN and Ti(BHPT)2 molecular films Ultraviolet Photoelectron Spectroscopy (UPS) can be used. The valence spectra of crystalline and amorphous films may be arbitrarily shifted to align peaks for ease of comparison in either linear intensity scale and/or logarithmic scale. FIG. 3 uses a linear intensity scale. As can be seen, the overall shapes of the crystalline and amorphous film spectra are similar: peaks and troughs are measured at similar energies regardless of morphology. In the 4CzIPN spectra, Peak A (at about −2 eV) is narrower with a Gaussian fitted peak with a 0.83 eV FWHM for the crystalline film in contrast to a 0.87 eV FWHM for the amorphous counterpart. Peaks B (at about −4 eV) and C (at about −6.5 eV), both being doublet peaks, are better resolved for c-4CzIPN than for a-4CzIPN. A similar trend can be observed in the Ti(BHPT)₂ spectra. Since the Ti(BHPT)₂ valence state spectra have non-negligible contributions from the 4CzIPN underlayer, a more accurate description of Ti(BHPT)₂ features should be made based on Peak D (at about −5 eV), where 4CzIPN has no distinct peak features. Peak D is visibly more defined for c-Ti(BHPT)₂ than for a-Ti(BHPT)₂, consistent with the trend described for 4CzIPN. Finally, the onset of valence states is sharper for the crystalline sample versus the amorphous sample. These data demonstrate improved electronic quality of the crystalline compared to the disordered stack.

As will be understood, these techniques may be used to identify materials suitable to grow an entirely crystalline architecture for, e.g., organic photovoltaic, LED, or transistor device structures. The superior charge transport properties of crystalline organics over the more-common amorphous materials could lead to more efficient devices. Thus, in some embodiments, the process may include repeating the process of identifying materials for at least one additional layer to be disposed in the architecture, in order to fabricate an electronic device. For example, in some embodiments, a second lattice matched material is identified and grown on the first lattice matched material. In some embodiments, a second template crystal structure may be grown at some point after the first lattice matched material is grown, and then a second material, lattice matched to the second template crystal structure, may be grown.

Although various embodiments which incorporate the teachings of the present invention have been shown and described in detail herein, those skilled in the art can readily devise many other varied embodiments that still incorporate these teachings. Thus, while the foregoing is directed to various embodiments of the present invention, other and further embodiments of the invention may be devised without departing from the basic scope thereof. As such, the appropriate scope of the invention is to be determined according to the claims.

What is claimed:

1. A method for heteroepitaxially growing organic crystals, comprising:
providing a template crystal; and
growing a first material on top of the template crystal, the first material being lattice matched to the template crystal and having a matching plane that has a lowest energy of all planes of a crystal structure of the first material.

2. The method of claim 1, wherein the first material is grown using physical vapor deposition.

3. A method for selecting materials for heteroepitaxially growing organic crystals, comprising:
identifying a template crystal structure and in-plane lattice parameters of the template crystal structure; and
determining a lattice matched material, by comparing at least one lattice parameter of each crystal plane of the lattice matched material to the in-plane lattice parameters of the template crystal structure, the lattice matched material having a matched plane, the matched plane having a lowest surface energy of all crystal planes of the lattice matched material.

4. The method of claim 3, wherein relative surface energies of the lattice matched material are calculated via first principles methods or estimated by applying Bravais-Friedel-Donnay-Harker law to determine a largest area of a crystal morphology, the largest area having a lowest energy surface.

5. The method of claim 3, wherein the lattice matched material is free of polymorphs.

6. The method of claim 3, wherein the lattice matched material is the most stable polymorph of a plurality of polymorphs.

7. The method of claim 3, further comprising growing the lattice matched material with the lowest surface energy on top of the template crystal structure.

8. The method of claim 7, wherein the lattice matched material is grown using physical vapor deposition.

9. A system for selecting materials for heteroepitaxially growing organic crystals, comprising:
at least one processor; and
a non-transitory computer readable storage medium containing instructions that, when executed, configures the at least one processor to, collectively:
receive information about a template crystal structure; and
identify a first material that is lattice matched to a template crystal structure by comparing at least one lattice parameter of each crystal plane of the first material to an in-plane lattice parameter of the template crystal structure, and has a matched plane to a plane of the template crystal structure, the matched plane having a lowest surface energy of all crystal planes of the first material.

10. The system of claim 9, wherein identifying the first material includes estimating relative surface energies of the first material by applying first principles methods or Bravais-Friedel-Donnay-Harker law to determine a largest area of a crystal morphology, the largest area having a lowest energy surface.

11. The system of claim 9, wherein the information about the template crystal structure comprises a material of the template crystal structure or a code representative of the material.

12. The system of claim 9, wherein the information about the template crystal structure comprises in-plane lattice parameters of the template crystal structure.

13. The system of claim 9, wherein the at least one processor is further configured to identify in-plane lattice parameters of the template crystal structure.

14. The system of claim 9, wherein the at least one processor is further configured to control a physical vapor deposition process to grow the first material on top of the template crystal structure.

15. The system of claim 9, wherein the at least one processor is further configured to:
determine growth conditions for growing the first material on top of the template crystal structure; and
store and/or transmit the growth conditions by:
storing the growth conditions on the non-transitory computer readable storage medium;
storing the growth conditions on a second, removable non-transitory computer readable storage medium;
sending the growth conditions to a remote device; or
a combination thereof.
